(19) United States
(12) Patent Application Publication
(10) Pub. No.: US 2026/0083028 A1
(43) Pub. Date: Mar. 19, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Keiichi AKAMA, Yokohama Kanagawa (JP)

(73) Assignee: Kioxia Corporation, Tokyo (JP)

(21) Appl. No.: 19/074,847

(22) Filed: Mar. 10, 2025

(30) Foreign Application Priority Data
Sep. 18, 2024 (JP) 2024-161257

(51) Int. Cl. H01L 23/498; H01L 21/48

(52) U.S. Cl. CPC H10W 90/701; H10W 70/093; H10W 70/685

(57) ABSTRACT

According to one embodiment, a semiconductor device includes a mounting board; a package board provided to face a main surface of the mounting board on a first direction side intersecting with the main surface; a metal bump provided between the main surface of the mounting board and the package board; a first underfill provided on a second direction side along the main surface as viewed from the metal bump; and a second underfill provided between the metal bump and the first underfill. The first and second underfills have different glass transition points.

### CROSS-REFERENCE TO RELATED APPLICATIONS

This application is based upon and claims the benefit of priority from Japanese Patent Application No. 2024-161257, filed on Sep. 18, 2024; the entire contents of which are incorporated herein by reference.

### FIELD

Embodiments described herein relate generally to a semiconductor device and a method of manufacturing the semiconductor device.

### BACKGROUND

There is a semiconductor device include a package with molded semiconductor chips and the like that is mounted on a board via a metal bump. Physical and thermal stresses applied to the semiconductor device may cause cracks in the metal bump.

### BRIEF DESCRIPTION OF THE DRAWINGS

FIGS. 1A and 1B are cross-sectional views schematically illustrating an exemplary configuration of a semiconductor device according to an embodiment;

FIGS. 2A and 2B are schematic diagrams illustrating the expansion and contraction of a mounting board and a semiconductor package;

FIGS. 3A and 3B are schematic diagrams illustrating the expansion and contraction of the mounting board and the semiconductor package;

FIG. 4 is a diagram illustrating an example of the glass transition point of an underfill according to the embodiment;

FIGS. 5A to 5D are cross-sectional views sequentially illustrating an example of a part of a procedure of a method of manufacturing a semiconductor device according to the embodiment;

FIG. 6 is a cross-sectional view schematically illustrating an exemplary configuration of a semiconductor device according to a first variation;

FIGS. 7A to 7C are cross-sectional views sequentially illustrating an example of a part of a procedure of a method of manufacturing the semiconductor device according to the first variation;

FIGS. 8A to 8B are diagrams schematically illustrating an exemplary configuration of a semiconductor device according to a second variation;

FIG. 9 is a cross-sectional view schematically illustrating an exemplary configuration of a semiconductor device according to a third variation; and

FIG. 10 is a schematic cross-sectional view illustrating an exemplary configuration of a semiconductor device according to a fourth variation.

### DETAILED DESCRIPTION

In general, according to one embodiment, a semiconductor device includes a mounting board; a package board provided to face a main surface of the mounting board on a first direction side intersecting with the main surface; a metal bump provided between the main surface of the mounting board and the package board; a first underfill provided on a second direction side along the main surface as viewed from the metal bump; and a second underfill provided between the metal bump and the first underfill. The first underfill and the second underfill have different glass transition points.

Exemplary embodiments of a semiconductor device and a method of manufacturing the semiconductor device will be explained below in detail with reference to the accompanying drawings. The present invention is not limited to the following embodiments.

### Embodiment

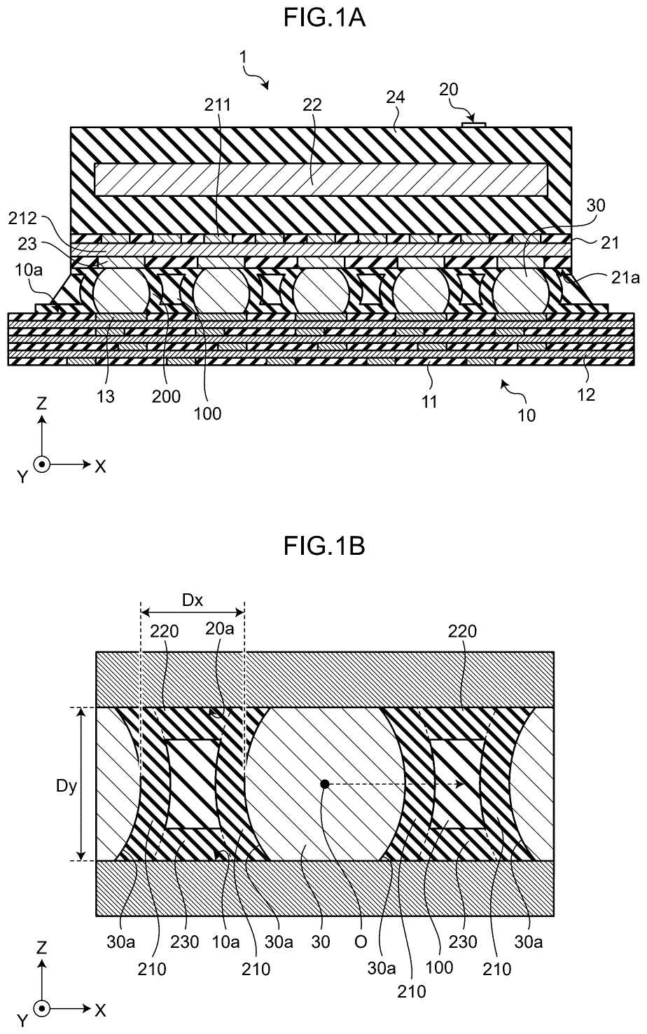

An embodiment will be now described in detail with reference to FIGS. 1A to 5D.

### Exemplary Configuration of Semiconductor Device

FIGS. 1A and 1B are cross-sectional views schematically illustrating an exemplary configuration of a semiconductor device 1 according to an embodiment. More specifically, FIG. 1A is an XZ cross-sectional view of the semiconductor device 1. FIG. 1B is an enlarged cross-sectional view at a height position of a metal bump 30 in FIG. 1A.

Moreover, herein, the side on which a semiconductor package 20 of the semiconductor device 1 is provided is referred to as the upper side, the side on which a mounting board 10 is provided is referred to as the lower side, and the vertical direction of the semiconductor device 1 is referred to as the Z direction. Additionally, directions intersecting with the Z direction are referred to as the X direction and the Y direction. The X direction and the Y direction lie along the direction of a plane of the mounting board 10, and the X direction and the Y direction are perpendicular to each other. The X direction is an example of the second direction. Furthermore, the side to which an arrow of each axis indicates is referred to as the positive direction, and the opposite side is referred to as a negative direction. The positive direction of Z is an example of the first direction.

As illustrated in FIG. 1A, the semiconductor device 1 includes the mounting board 10, the semiconductor package 20, and the metal bump 30.

The mounting board 10 is configured as a multilayer board, with an insulating layer 11 and a conductive layer 12 laminated alternately multiple times. An electrode 13 is arranged on an upper surface 10a that is a first surface of the mounting board 10. The electrode 13 is an example of a first connection portion.

The insulating layer 11 is formed of, for example, a carbon fiber, a glass fiber, an aramid fiber, or the like impregnated with a thermosetting resin such as epoxy resin before curing. The conductive layer 12 and the electrode 13 are formed of, for example, a metal such as Cu. The conductive layer 12 has a wiring pattern and is connected to the electrode 13. An electrode (not illustrated) arranged on the lower surface of the mounting board 10 is electrically connected to an external power source such as a host computer.

Above the mounting board 10, the semiconductor package 20 is provided to face the upper surface 10a of the mounting board 10. The semiconductor package 20 includes a resin substrate 21, a semiconductor chip 22, an electrode 23, and a molding resin 24. The semiconductor package 20 is an example of a package board.

The resin substrate 21 includes a conductive layer 211 and an insulating layer 212. The resin substrate 21 has a lower surface 21a, which is a second surface of the resin substrate 21 and faces the upper surface 10a of the mounting board 10. The electrode 23 is arranged on the lower surface 21a of the resin substrate 21. The lower surface 21a is an example of the second surface, and the electrode 23 is an example of a second connection portion.

The insulating layer 212 is formed of, for example, a carbon fiber, a glass fiber, an aramid fiber, or the like impregnated with a thermosetting resin such as epoxy resin before curing. The conductive layer 211 and the electrode 23 are formed of, for example, a metal such as Cu. The conductive layer 211 has a wiring pattern and is connected to the electrode 23.

The semiconductor chip 22 is provided above the resin substrate 21. The semiconductor chip 22 is a small piece obtained by segmenting a silicon substrate or the like and incorporates a semiconductor element (not illustrated). The semiconductor element is, for example, a NAND flash memory or the like. The semiconductor chip 22 is connected to the conductive layer 211 of the resin substrate 21 via a wire (not illustrated). This arrangement establishes an electrical connection between the semiconductor chip 22 and the electrode 23.

The semiconductor chip 22 and the wire or the like (not illustrated) are sealed to the resin substrate 21 by the molding resin 24.

In the present embodiment, the semiconductor package 20 is described as having one semiconductor chip 22, but this is not the only configuration possible. The semiconductor package 20 may have a plurality of semiconductor chips.

The plurality of metal bumps 30 is arranged between the upper surface 10a of the mounting board 10 and the lower surface 21a of the resin substrate 21. The metal bump 30 is formed, for example, in a ball shape. The metal bump 30 has an upper end connected to the electrode 13 arranged on the upper surface 10a of the mounting board 10, and the metal bump 30 has a lower end connected to the electrode 23 arranged on the lower surface 21a of the resin substrate 21. This arrangement establishes an electrical connection between the mounting board 10 and the semiconductor package 20.

Between the plurality of metal bumps 30, underfills 100 and 200 are arranged. The underfills 100 and 200 each include a thermosetting epoxy resin, or the like. The underfill 100 is an example of a first underfill, and the underfill 200 is an example of a second underfill.

Specifically, the plurality of metal bumps 30 is arranged, for example, side by side along the X direction. Thus, as illustrated in FIG. 1B, side surfaces 30a of adjacent metal bumps 30 face each other in the X direction. The side surface 30a of the metal bump 30 is the portion, of the surface of the metal bump 30, which is exposed between the upper surface 10a of the mounting board 10 and the lower surface 21a of the resin substrate 21. The side surface 30a is an example of a third surface.

The underfill 200 covers the side surface 30a of the metal bump 30. The portion of the underfill 200 that covers the side surface 30a of the metal bump 30 is hereinafter referred to as a first portion 210 in some cases. The first portion 210 has a thickness smaller than half a distance Dx between the side surfaces 30a facing each other in the X direction. As a result, a space is created between the first portions 210 opposing to each other in the X direction.

Additionally, the underfill 200 covers both the upper surface 10a of the mounting board 10 and the lower surface 21a of the resin substrate 21. Hereinafter, in some cases, the portion of the underfill 200 that covers the lower surface 21a of the resin substrate 21 is referred to as a second portion 220, and the portion that covers the upper surface 10a of the mounting board 10 is referred to as a third portion 230.

The second portion 220 and the third portion 230 face each other in the Z direction. The total thickness of the second portion 220 and the third portion 230 is smaller than a distance Dy between the upper surface 10a of the mounting board 10 and the lower surface 21a of the resin substrate 21. As a result, a space is created between the second portion 220 and the third portion 230 that face each other.

Furthermore, the second portion 220 is connected to an upper end of the first portion 210, and the third portion 230 is connected to a lower end of the first portion 210. In other words, the underfill 200 continuously covers the side surface 30a of the metal bump 30, the upper surface 10a of the mounting board 10, and the lower surface 21a of the resin substrate 21.

The portion of the space between the upper surface 10a of the mounting board 10 and the lower surface 21a of the resin substrate 21 that is not occupied by the first portion 210, the second portion 220, and the third portion 230 is filled with the underfill 100. In other words, as viewed in the X direction from a center point O of the metal bump 30 (dashed line in FIG. 1B), the metal bump 30, the first portion 210, and the underfill 100 are arranged in this order. In other words, the underfill 200 (the first portion 210) is arranged between the metal bump 30 and the underfill 100.

Moreover, herein, although the description above states that the underfill 200 continuously covers the upper surface 10a of the mounting board 10, the side surface 30a of the metal bump 30, and the lower surface 21a of the resin substrate 21, this is not the only configuration possible. For example, the configuration is acceptable as long as the underfill 200 covers at least a portion of each of the upper surface 10a of the mounting board 10, the side surface 30a of the metal bump 30, and the lower surface 21a of the resin substrate 21. Additionally, it is acceptable that the underfill 100 is arranged in at least a part of the portion where the first portion 210, the second portion 220, and the third portion 230 are not placed, and the portion may not necessarily be filled up with the underfill 100.

Incidentally, in order to extend the lifespan of the semiconductor device 1, the semiconductor device 1 is required, for instance, to have high resistance to a physical stress being applied at the time of dropping, or to a thermal stress being applied at the time of exposure to high temperature or low-temperature environments. To evaluate the resistance to the physical stress and the thermal stress, for example, a drop test and a temperature cycling test (TCT) are performed prior to shipment of the semiconductor device 1.

The thermal expansion coefficient of the semiconductor chip 22 included in the semiconductor package 20 is relatively low. On the other hand, most parts of the mounting board 10 are formed of resin with a relatively high thermal expansion coefficient. Thus, the thermal expansion coefficient of the mounting board 10 is larger than that of the semiconductor package 20. If the thermal expansion coefficients of the mounting board 10 and the semiconductor package 20 differ, stress is applied to the metal bump 30 connecting these two components, due to the differences in expansion and contraction between the mounting board 10 and the semiconductor package 20.

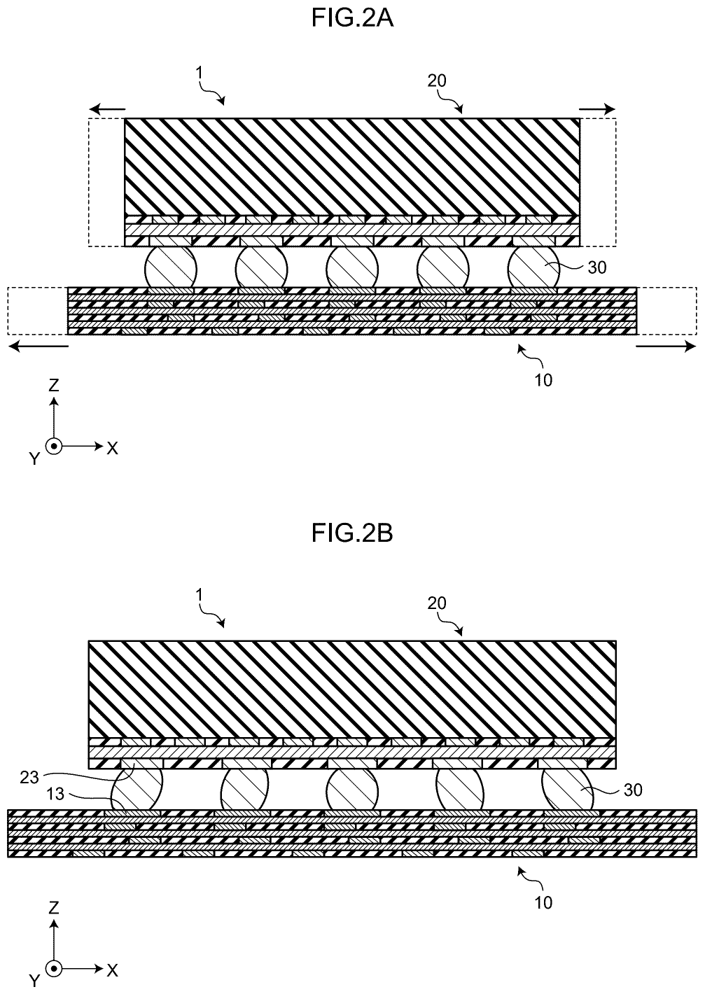

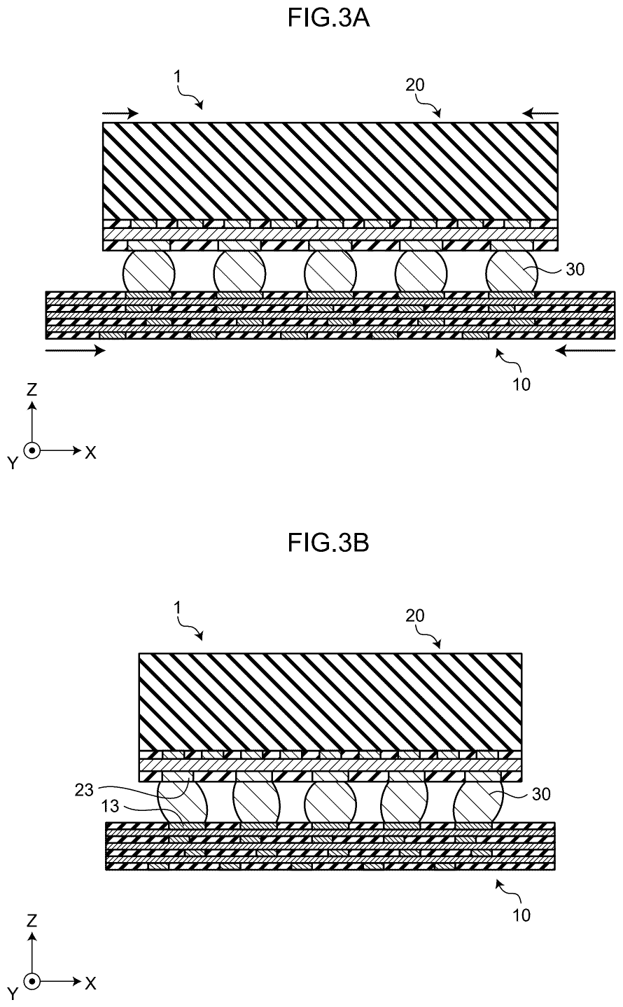

FIGS. 2A to 2B and 3A to 3B are schematic diagrams illustrating the expansion and contraction of the mounting board 10 and the semiconductor package 20. More specifically, FIG. 2A and FIG. 2B illustrate the expansion of the mounting board 10 and the semiconductor package 20 under a high-temperature environment, while FIG. 3A and FIG. 3B illustrate the contraction of the mounting board 10 and the semiconductor package 20 under a low-temperature environment. The high-temperature environment is, for example, 125° C., and the low-temperature environment is, for example, −40°C.

For example, in the case where the semiconductor device 1 is placed in a high-temperature environment, the mounting board 10 and the semiconductor package 20 expand as indicated by the arrows and dashed lines in FIG. 2A.

Such expansion may cause the mounting board 10 and the semiconductor package 20 to warp in the up-down direction. The difference in thermal expansion coefficients causes the degree of expansion of the mounting board 10 to be greater than that of the semiconductor package 20. Thus, as illustrated in FIG. 2B, the lower end of the metal bump 30 is subjected to greater stress directed outward from the semiconductor device 1. This may cause the lower end of the metal bump 30 to distort toward the outside.

On the other hand, in the case where the semiconductor device 1 is placed in a low-temperature environment, the mounting board 10 and the semiconductor package 20 contract as indicated by the arrows and dashed lines in FIG. 3A. The contraction causes the mounting board 10 and the semiconductor package 20 to warp in the up-down direction in some cases. The difference in thermal expansion coefficients causes the degree of contraction of the mounting board 10 to be greater than that of the semiconductor package 20. Thus, as illustrated in FIG. 3B, the lower end of the metal bump 30 is subjected to greater stress toward the inside of the semiconductor device 1. This may cause the lower end of the metal bump 30 to distort toward the inside.

In the case where the thermal stress is applied to the metal bump 30 as mentioned above, the metal bump 30 may fracture at the interface with the electrodes 13 and 23, or the metal bump 30 may peel off from the electrodes 13 and 23. Similarly, in the case where physical stress is applied to the metal bump 30, the metal bump 30 may fracture at the interface with the electrodes 13 and 23, or the metal bump 30 may peel off from the electrodes 13 and 23. This may result in the failure of the semiconductor device 1. Moreover, the fracture or peeling of the metal bump 30 is hereinafter sometimes referred to as a “crack”.

Furthermore, among the plurality of metal bumps 30 arranged between the upper surface 10a of the mounting board 10 and the lower surface 21a of the resin substrate 21, the metal bump 30 arranged closer to the outer periphery is subjected to greater thermal stress as described above. In other words, the metal bump 30 arranged closer to the outer periphery is more susceptible to developing cracks.

To suppress the occurrence of cracks in the metal bump 30 as described above, the underfills 100 and 200 of the present embodiment have different glass transition points.

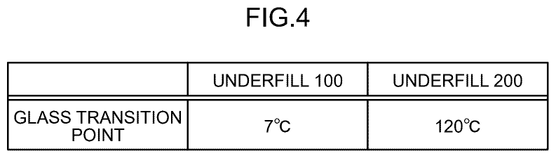

FIG. 4 is a diagram illustrating an example of the glass transition points of the underfills 100 and 200 according to the present embodiment.

As illustrated in FIG. 4, the glass transition point of the underfill 100 is, for example, 7° C., and the glass transition point of the underfill 200 is, for example, 120° C. In other words, the underfill 200 has a higher glass transition point than the underfill 100.

In the case where the semiconductor device 1 is placed in an environment with a temperature lower than, for example, 120° C., the underfill 200 becomes glassy and relatively hard having a low thermal expansion coefficient in that environment. Covering the upper surface 10a of the mounting board 10, the side surface 30a of the metal bump 30, and the lower surface 21a of the resin substrate 21 with the underfill 200 makes it possible to alleviate the thermal stress applied to the metal bump 30 in the case where the mounting board 10 and the semiconductor package 20 expand or contract. This suppresses the occurrence of cracks in the metal bump 30.

Additionally, in the case where the semiconductor device 1 is placed in an environment with a temperature higher than, for example, 7° C., the underfill 100 becomes rubbery and relatively soft in that environment. Filling the space between the upper surface 10a of the mounting board 10 and the lower surface 21a of the resin substrate 21 where the underfill 200 is not placed with such underfill 100 makes it possible to alleviate the physical stress being applied to the metal bump 30 when the semiconductor device 1 is dropped. This suppresses the occurrence of cracks in the metal bump 30.

Moreover, although the present embodiment employs the underfills having their respective glass transition points illustrated in FIG. 4, the underfills applicable to the present embodiment are not limited to the example illustrated in FIG. 4. For example, the underfill may be selected based on the temperature of the environment in which the semiconductor device 1 is placed. In the case of selecting an underfill, for example, it may be preferable to select, as the underfill 100, one with a glass transition point lower than the temperature of the environment in which the semiconductor device 1 is placed and select, as the underfill 200, one with a glass transition point higher than the temperature of the environment. In addition, it is desirable that both the underfills 100 and 200 have a low thermal expansion coefficient.

### Method of Manufacturing Semiconductor Device

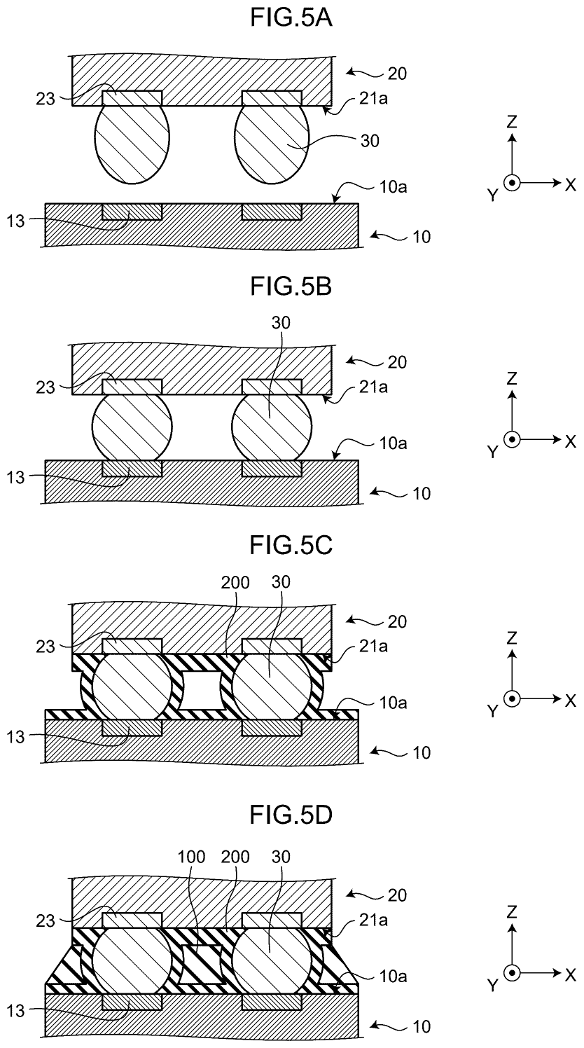

A method of manufacturing the semiconductor device 1 according to the embodiment is now described with reference to FIGS. 5A to 5D.

FIGS. 5A to 5D are cross-sectional views sequentially illustrating a part of a procedure of the method of manufacturing the semiconductor device 1 according to the embodiment. Moreover, in FIGS. 5A to 5D, the configuration above the electrode 23 of the semiconductor package 20 and the configuration below the electrode 13 of the mounting board 10 are omitted from the illustration.

In the method of manufacturing the semiconductor device according to the embodiment, the semiconductor package 20 is formed in advance prior to the processing of FIG. 5A.

As illustrated in FIG. 5A, after the semiconductor package 20 is formed, the plurality of metal bumps 30 that is connectable to the electrode 23 is formed on the lower surface 21a of the resin substrate 21 to mount the semiconductor package 20 on the mounting board 10. The metal bump 30 is formed using, for example, techniques such as thermocompression bonding, ultrasonic bonding, or mass reflow that melts a plurality of solders in an array to form a plurality of solder balls at once. Subsequently, the semiconductor package 20, with the metal bump 30 formed, is picked up by a picker or the like, with the semiconductor package 20 facing upward, and is placed to face the upper surface 10a of the mounting board 10.

Then, as illustrated in FIG. 5B, the semiconductor package 20 is mounted on the mounting board 10 via the metal bump 30. Specifically, the electrode 13 mounting board and the metal bump 30 of the mounting board 10 are stacked on top of each other and heated to a temperature of 100° C. or higher in an oven or the like. This causes the electrode 13 and the metal bump 30 to be bonded, thus electrically connecting the mounting board 10 and the semiconductor package 20 to each other.

Subsequently, as illustrated in FIG. 5C, the underfill 200 is formed between the upper surface 10a of the mounting board 10 and the lower surface 21a of the resin substrate 21. Specifically, a paste-like liquid, which is the uncured underfill 200, is applied to the upper surface 10a of the mounting board 10, the side surface 30a of the metal bump 30, and the lower surface 21a of the resin substrate 21 using, for example, at least one of techniques of coating, adhesion, or spraying. In the case of applying the liquid, the thickness of the liquid to be applied is adjusted so that spaces are created between adjacent metal bumps 30 and between the upper surface 10a of the mounting board 10 and the lower surface 21a of the resin substrate 21. It is because of the reason that those spaces are to be filled up with the underfill 100 later. After applying the liquid, the assembly is heated to a temperature of 100° C. or higher in an oven or the like. This causes the underfill 200 to be formed.

Subsequently, as illustrated in FIG. 5D, the underfill 100 is formed in a portion of the space between the upper surface 10a of the mounting board 10 and the lower surface 21a of the resin substrate 21, where the underfill 200 is not formed. Specifically, a paste-like liquid, which is the uncured underfill 100, is injected into the space between the upper surface 10a of the mounting board 10 and the lower surface 21a of the resin substrate 21 using, for example, a dispensing nozzle or the like. The liquid spreads along the portion of the space between the upper surface 10a of the mounting board 10 and the lower surface 21a of the resin substrate 21 where the underfill 200 is not formed. Then, the assembly is heated to a temperature of 100° C. or higher in an oven or the like. This causes the underfill 100 to be formed.

Subsequently, the mounting board 10 is segmented into individual pieces (not illustrated). This completes the manufacturing of the semiconductor device 1 of the embodiment.

### Overview

The semiconductor device 1 of the present embodiment includes the mounting board 10, the resin substrate 21 provided opposite the upper surface 10a of the mounting board 10, and the metal bump 30 provided between the upper surface 10a of the mounting board 10 and the resin substrate 21. As viewed from the metal bump 30, the underfill 100 is provided on the X-direction side, and the underfill 200 is provided between the metal bump 30 and the underfill 100. The underfill 100 has a different glass transition point than that of the underfill 200.

An underfill with a higher glass transition point is relatively hard and has a low thermal expansion coefficient. Arranging such an underfill around the metal bump 30 makes it possible to alleviate the thermal stress applied to the metal bump 30. On the other hand, an underfill with a lower glass transition point is relatively soft. Arranging such an underfill around the metal bump 30 makes it possible to alleviate the physical stress applied to the metal bump 30 due to an impact of dropping, or the like. By arranging two types of underfills with different glass transition points around the metal bump 30, it is possible to alleviate both thermal stress and physical stress, thereby suppressing the occurrence of cracks in the metal bump 30.

### First Variation

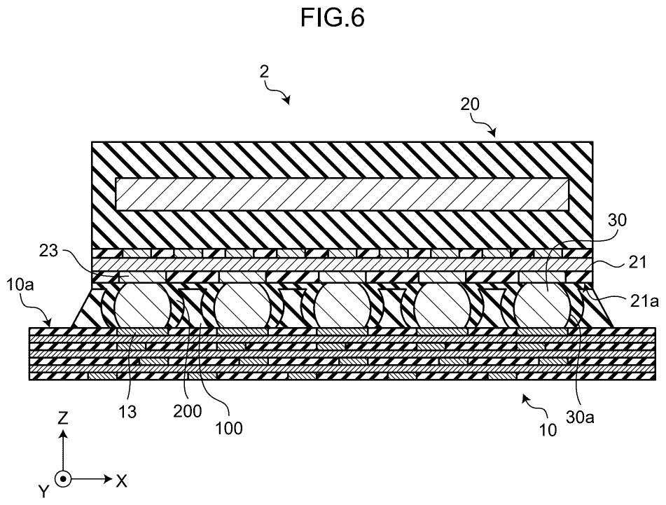

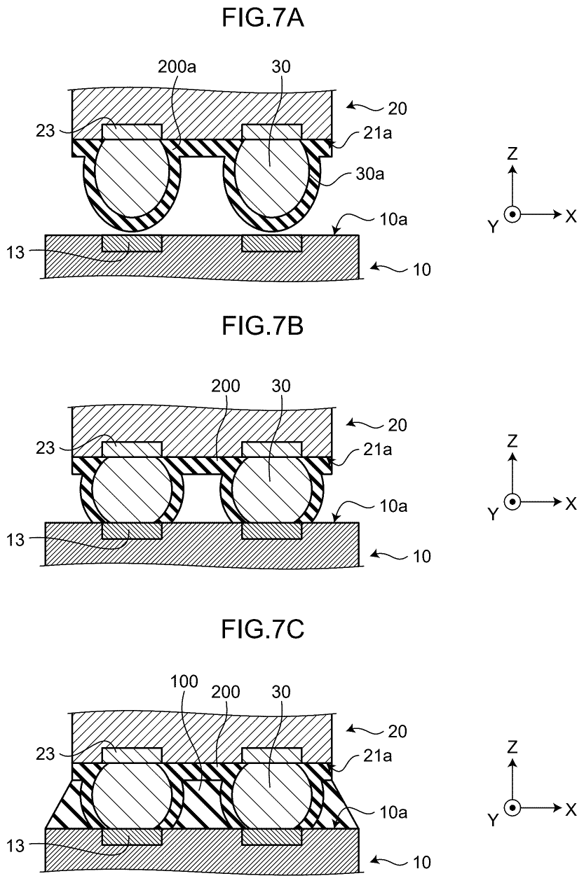

A semiconductor device 2 according to a first variation is now described with reference to FIGS. 6 to 7C.

In the semiconductor device 2 according to the first variation, the location where an underfill 200 is provided differs from that in the previously described embodiment. Moreover, in the following description, components similar to those in the previously described embodiment are assigned similar signs, and their descriptions may be omitted.

FIG. 6 is a cross-sectional view schematically illustrating an exemplary configuration of the semiconductor device 2 according to the first variation.

As illustrated in FIG. 6, in the semiconductor device 2 according to the first variation, an upper surface 10a of a mounting board 10 is not covered with the underfill 200. In other words, the underfill 200 covers a lower surface 21a of a resin substrate 21 and a side surface 30a of a metal bump 30.

FIGS. 7A to 7C are cross-sectional views sequentially illustrating a part of the procedure of the method of manufacturing the semiconductor device 2 according to the first variation. Moreover, in the method of manufacturing the semiconductor device according to the first variation, a semiconductor package 20 is also formed in advance prior to the processing illustrated in FIG. 7A.

As illustrated in FIG. 7A, after forming the semiconductor package 20 and the metal bump 30, and before mounting the semiconductor package 20 on the mounting board 10, a paste-like liquid 200a, which is the uncured underfill 200, is applied to the entire lower surface, including the lower surface 21a of the resin substrate 21 and the side surface 30a of the metal bump 30.

Subsequently, as illustrated in FIG. 7B, the electrode 13 mounting board and the metal bump 30 of the mounting board 10 are stacked on top of each other and heated to a temperature of 100° C. or higher in an oven or the like. This causes the mounting board 10 and the semiconductor package 20 to be electrically connected to each other. In addition, the liquid 200a is cured to form the underfill 200.

Subsequently, as illustrated in FIG. 7C, an underfill 100 is formed in the portion of the space between the upper surface 10a of the mounting board 10 and the lower surface 21a of the resin substrate 21 where the underfill 200 is not formed.

The semiconductor device and the method of manufacturing the semiconductor device according to the first variation provide effects similar to those of the semiconductor device 1 and the method of manufacturing the semiconductor device 1 of the previously described embodiment.

### Second Variation

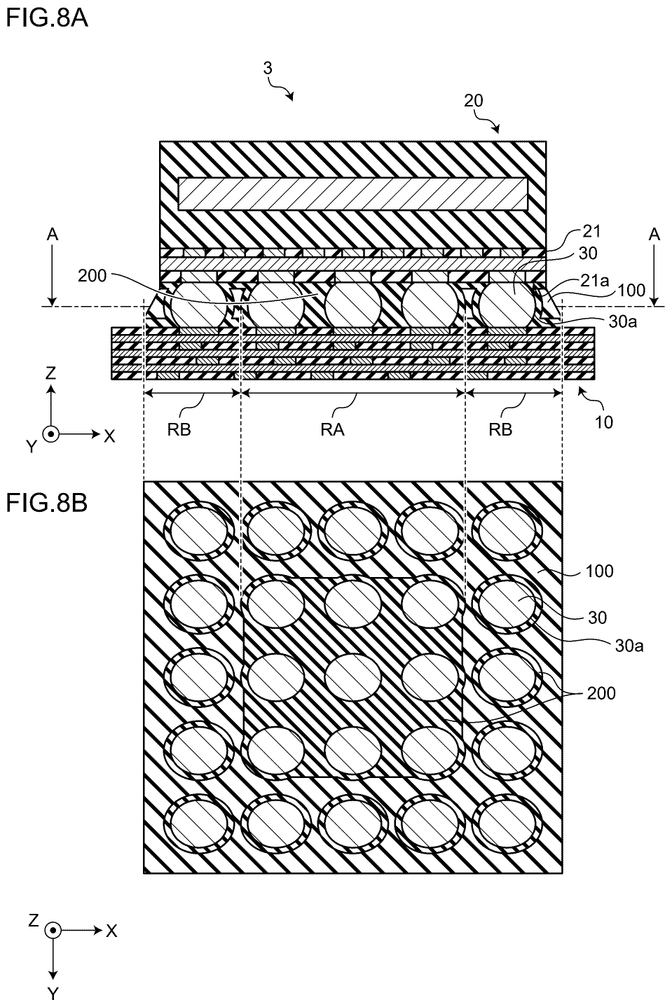

A semiconductor device 3 according to a second variation is now described with reference to FIG. 8A to FIG. 8B. In the semiconductor device 3 according to the second variation, the location where an underfill 100 is provided is different from that of the previously described embodiment. Moreover, in the following description, components similar to those in the previously described embodiment are assigned similar signs, and their descriptions may be omitted.

FIG. 8A to FIG. 8B are diagrams schematically illustrating an exemplary configuration of the semiconductor device 3 according to the second variation. More specifically, FIG. 8A is an XZ cross-sectional view of the semiconductor device 3, and corresponds to FIG. 1A. FIG. 8B is a cross-sectional view taken along line AA in FIG. 8A. In other words, FIG. 8B is an XY cross-sectional view of the semiconductor device 3 at a height position between an upper surface 10a of a mounting board 10 and a lower surface 21a of a resin substrate 21.

As illustrated in FIGS. 8A and 8B, among the spaces between the upper surface 10a of the mounting board 10 and the lower surface 21a of the resin substrate 21, a space RA corresponding to the central side of the lower surface 21a of the resin substrate 21 is filled with an underfill 200. In other words, an underfill 100 is not placed around a metal bump 30 placed in the space RA.

On the other hand, both the underfill 100 and the underfill 200 are arranged in a space RB corresponding to the outer periphery side of the lower surface 21a of the resin substrate 21. In other words, the underfill 100 and the underfill 200 are placed around the metal bump 30 placed in the space RB. The underfill 100 and underfill 200 in the space RB have the configuration corresponding to the underfill 100 and underfill 200, respectively, in the previously described embodiment, and therefore, a description thereof is omitted here.

As described above with reference to FIGS. 2A to 2B and FIGS. 3A to 3B, among the multiple metal bumps 30 arranged between the upper surface 10a of the mounting board 10 and the lower surface 21a of the resin substrate 21, the thermal stress applied to the metal bump 30 increases for those arranged closer to the outer side. Thus, such selective arrangement of the underfill 200 capable of alleviating thermal stress in the space RB makes it possible to more efficiently alleviate the thermal stress applied to the metal bump 30 arranged in the space RB.

The semiconductor device and the method of manufacturing the semiconductor device according to the second variation provide effects similar to those of the semiconductor device 1 and the method of manufacturing the semiconductor device 1 according to the previously described embodiment. Moreover, the second variation can be applied not only to the previously described embodiment but also to a variation of the first variation.

### Third Variation

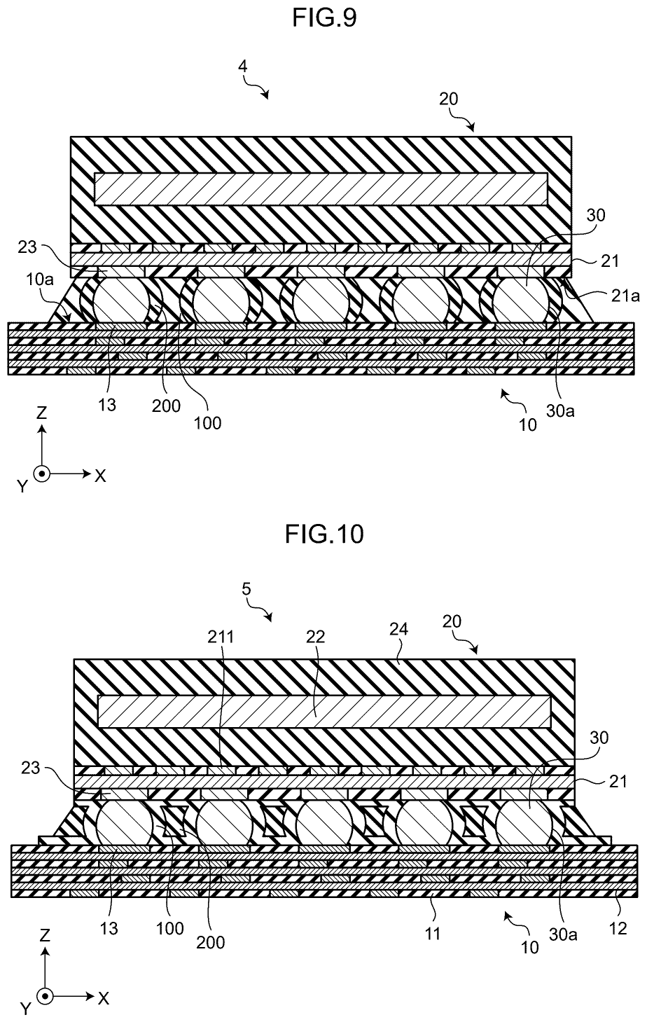

A semiconductor device 4 according to a third variation is now described with reference to FIG. 9.

The third variation is a variation example corresponding to the embodiment and the first variation. In other words, in the semiconductor device 4 according to the third variation, the location where an underfill 200 is provided is different from that of the previously described embodiment and the first variation. Moreover, in the following description, components similar to those in the previously described embodiment are assigned similar signs, and their descriptions may be omitted.

FIG. 9 is a cross-sectional view schematically illustrating an exemplary configuration of the semiconductor device 4 according to the third variation.

As illustrated in FIG. 9, in the semiconductor device 4 according to the third variation, an upper surface 10a of a mounting board 10 and a lower surface 21a of a resin substrate 21 are not covered with an underfill 200. In other words, the underfill 200 covers a side surface 30a of a metal bump 30.

The semiconductor device 4 as described above can be obtained by covering the lower surface 21a of the resin substrate 21 with a mask film (not illustrated) in the case of applying a liquid 200a in FIG. 7A, of the steps described in FIGS. 7A to 7C of the first variation. This is intended for the mask film to prevent the paste-like liquid 200a from being applied to the lower surface 21a of the resin substrate 21. The mask film is removed, for example, before an underfill 100 is formed.

The semiconductor device and the method of manufacturing the semiconductor device according to the third variation provide effects similar to those of the semiconductor device 1 and the method of manufacturing the semiconductor device 1 according to the previously described embodiment.

### Fourth Variation

A fourth variation is now described with reference to FIG. 10.

In a semiconductor device 5 according to the fourth variation, the locations where underfills 100 and 200 are reversed compared to those of the previously described embodiment. Moreover, in the following description, components similar to those in the previously described embodiment are assigned similar signs, and their descriptions may be omitted.

FIG. 10 is a schematic cross-sectional view illustrating an exemplary configuration of the semiconductor device 5 according to the fourth variation.

As illustrated in FIG. 10, an underfill 100 covers an upper surface 10a of a mounting board 10, a side surface 30a of a metal bump 30, and a lower surface 21a of a resin substrate 21. An underfill 200 fills the portion of the space between the upper surface 10a of the mounting board 10 and the lower surface 21a of the resin substrate 21 where the underfill 100 is not placed. The underfill 100 is an example of a second underfill, and the underfill 200 is an example of a first underfill. The underfill 100 and the underfill 200 in the variation 4 have a configuration corresponding to the underfill 100 and the underfill 200 in the embodiment, except that the locations thereof are reversed, and therefore, a description thereof will be omitted here.

The semiconductor device 5 of the variation 4 provides effects similar to those of the semiconductor device 1 according to the previously described embodiment. Moreover, the fourth variation can be applied not only to the previously described embodiment but also to a variation of the first and third variations.

### Other Variations

In the above-described embodiment and variations, an example is provided in which two underfills with different glass transition points are provided between the upper surface 10a of the mounting board 10 and the lower surface 21a of the resin substrate 21, but the number of underfills is not limited thereto. For example, three underfills with different glass transition points may be provided between the upper surface 10a of the mounting board 10 and the lower surface 21a of the resin substrate 21.

The method of manufacturing the semiconductor device described in the claims may also include methods described in the following supplementary notes.

### Supplementary Note 1

The method of manufacturing the semiconductor device according to claim 10 or 11, in which the second underfill has a higher glass transition point than that of the first underfill.

### Supplementary Note 2

The method of manufacturing the semiconductor device according to claim 10 or 11, in which the first underfill has a higher glass transition point than that of the second underfill.

### Supplementary Note 3

The method of manufacturing the semiconductor device according to claim 10 or 11, in which the second underfill covers at least a portion of the second surface.

### Supplementary Note 4

The method of manufacturing the semiconductor device according to claim 10 or 11, in which the second underfill covers at least a portion of the first surface.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a mounting board;
a package board provided to face a first surface of the mounting board on a first direction side intersecting with the first surface;
a metal bump provided between the first surface of the mounting board and the package board;
a first underfill provided on a second direction side along the first surface as viewed from the metal bump; and
a second underfill provided between the metal bump and the first underfill, wherein
the first underfill and the second underfill have different glass transition points.

2. The semiconductor device according to claim 1, wherein
the second underfill has the glass transition point higher than the glass transition point of the first underfill.

3. The semiconductor device according to claim 1, wherein
the first underfill has the glass transition point higher than the glass transition point of the second underfill.

4. The semiconductor device according to claim 1, wherein
the second underfill covers at least a portion of a second surface of the package board, the second surface facing the mounting board.

5. The semiconductor device according to claim 4, wherein
the second underfill covers at least a portion of the first surface of the mounting board.

6. The semiconductor device according to claim 1, wherein
the mounting board includes:
a conductive layer; and
a first connection portion connected to the conductive layer, the first connection portion being formed on the first surface,
the package board includes:
one or more semiconductor chips; and
a second connection portion connected to the one or more semiconductor chips, the second connection portion being formed on a second surface facing the mounting board, and
the metal bump connects the first connection portion to the second connection portion.

7. The semiconductor device according to claim 1, wherein the metal bump is formed in a ball shape.

8. The semiconductor device according to claim 1, further comprising:
a plurality of metal bumps including the metal bump that is arranged between the first surface of the mounting board and the package board, wherein
the second underfill is filled between two adjacent metal bumps arranged on a central side of the package board among the plurality of metal bumps.

9. The semiconductor device according to claim 2, wherein
the first underfill has the glass transition point lower than a temperature of an environment in which the semiconductor device is placed, and
the second underfill has the glass transition point higher than the temperature of the environment.

10. A method of manufacturing a semiconductor device, the method comprising:
mounting a package board on a first surface of a mounting board via a plurality of metal bumps, the package board having the plurality of metal bumps on a second surface thereof;
forming a second underfill to cover at least a portion of a third surface of each of the plurality of metal bumps, the third surfaces being exposed between the first surface and the second surface; and
forming a first underfill in a portion, between the first surface and the second surface, in which the second underfill is not formed, wherein
the first underfill and the second underfill have different glass transition points.

11. A method of manufacturing a semiconductor device, the method comprising:
forming a second underfill to cover at least a portion of each of a plurality of metal bumps provided on a second surface of a package board;
mounting the package board on a first surface of a mounting board via the plurality of metal bumps; and
forming a first underfill in a portion, between the first surface and the second surface, in which the second underfill is not formed, wherein
the first underfill and the second underfill have different glass transition points.

12. The method of manufacturing the semiconductor device according to claim 10, wherein
the second underfill is formed using at least one technique of coating, adhesion, and spraying.

13. The method of manufacturing the semiconductor device according to claim 10, wherein
the second underfill has the glass transition point higher than the glass transition point of the first underfill.

14. The method of manufacturing the semiconductor device according to claim 10, wherein
the first underfill has the glass transition point higher than the glass transition point of the second underfill.

15. The method of manufacturing the semiconductor device according to claim 11, wherein
the second underfill is formed using at least one technique of coating, adhesion, and spraying.

16. The method of manufacturing the semiconductor device according to claim 11, wherein
the second underfill has the glass transition point higher than the glass transition point of the first underfill.

17. The method of manufacturing the semiconductor device according to claim 11, wherein
the first underfill has the glass transition point higher than the glass transition point of the second underfill.
